(19) United States
(12) Patent Application Publication
(10) Pub. No.: US 2025/0301833 A1
(43) Pub. Date: Sep. 25, 2025

(54) DISPLAY PANEL

(71) Applicant: AUO Corporation, Hsinchu (TW)

(72) Inventors: Teng-Wei Huang, Hsinchu (TW); Tzu-Hsuan Yang, Hsinchu (TW); Hsun-Chen Chu, Hsinchu (TW)

(73) Assignee: AUO Corporation, Hsinchu (TW)

(21) Appl. No.: 18/788,165

(22) Filed: Jul. 30, 2024

(30) Foreign Application Priority Data
Mar. 19, 2024 (TW) 113110073

(51) Int. Cl. H01L 33/60; H01L 25/075

(52) U.S. Cl. CPC H10H 20/856; H01L 25/0753

(57) ABSTRACT

A display panel including a plurality of pixel sets is provided. Each of the pixel set includes at least one first pixel and at least one second pixel. The first pixel includes a first light emitting element and a first light blocking structure. The second pixel includes a second light emitting element and a second light blocking structure. The first light blocking structure includes a bottom portion, a slope portion, and a top portion that are integrally formed. The second light emitting element and the first light emitting element emit light of a same color. The second light blocking structure is disposed symmetrically with respect to a fictitious plane, where the fictitious plane passes through a geometric center of a light emitting surface of the second light emitting element.

### CROSS-REFERENCE TO RELATED APPLICATION

This application claims the priority benefit of Taiwan application serial no. 113110073, filed on Mar. 19, 2024. The entirety of the above-mentioned patent application is hereby incorporated by reference herein and made a part of this specification.

### BACKGROUND

### Technical Field

The disclosure relates to a display panel.

### Description of Related Art

Since micro light emitting diodes have the characteristics of wide viewing angle, micro light emitting diode display panels suffers from snooping issues at large viewing angles. Therefore, it is necessary to use a light blocking structure to limit the viewing angle. In addition, how to switch between the normal mode of wide viewing angle and the private mode of restricted viewing angle in response to different situational needs has become an urgent problem that needs to be solved.

### SUMMARY

The disclosure provides a display panel that can switch between a normal mode and a private mode and avoid large angle light leakage.

According to an embodiment of the disclosure, a display panel including a plurality of pixel sets is provided. Each pixel set includes at least one first pixel and at least one second pixel. The first pixel includes a first light emitting element and a first light blocking structure. The second pixel includes a second light emitting element and a second light blocking structure. The first light blocking structure is configured on a light emitting side of the first light emitting element and includes a bottom portion, a slope portion, and a top portion that are integrally formed. The second light emitting element and the first light emitting element emit light of a same color. The second light blocking structure is configured on a light emitting side of the second light emitting element, and the second light blocking structure is disposed symmetrically with respect to a first fictitious plane, where the first fictitious plane passes through a geometric center of a light emitting surface of the second light emitting element.

Based on the above, the display panel provided by the embodiment of the disclosure uses the first pixels and the second pixels with different light blocking structures to switch between the normal mode and the private mode. The top portion of the light blocking structure in the first pixel is used to limit the horizontal viewing angle of the display panel, the bottom portion and the slope portion of the light blocking structure in the first pixel are used to avoid large angle light leakage, and the three-dimensional light blocking structure has a light collection effect, so that energy consumption can be reduced.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1A, FIG. 1B, and FIG. 1C are top views of display panels according to some embodiments of the disclosure.

FIG. 2 is a schematic diagram of a first pixel according to an embodiment of the disclosure.

FIG. 3A and FIG. 3B are schematic diagrams of first pixels and second pixels according to an embodiment of the disclosure.

FIG. 4, FIG. 5, FIG. 6, FIG. 7, FIG. 8, FIG. 9, and FIG. 10 are schematic diagrams of first pixels according to some embodiments of the disclosure.

### DESCRIPTION OF THE EMBODIMENTS

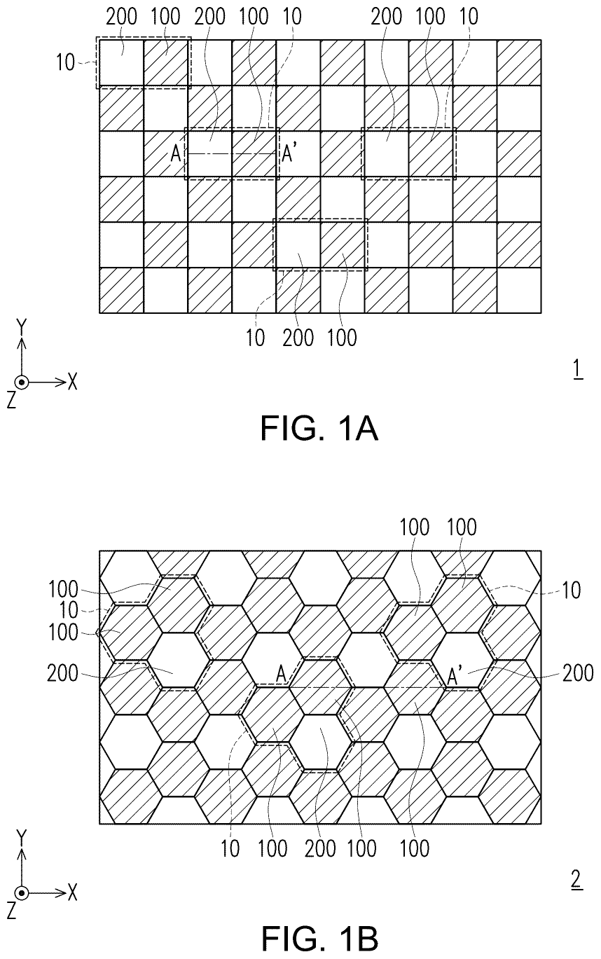

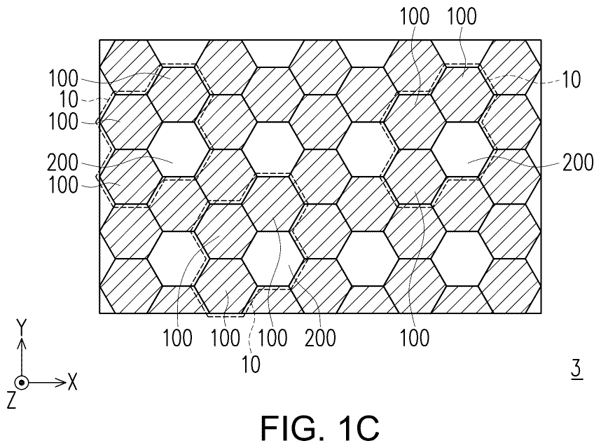

Referring to FIG. 1A, a top view of a display panel according to an embodiment of the disclosure is shown. A display panel 1 includes a plurality of pixel sets 10 arranged in an array on an XY plane. Each pixel set 10 includes a first pixel 100 and a second pixel 200. A Z direction in FIG. 1A is a positive viewing angle direction of the display panel 1. When viewed from a positive X direction toward a negative X direction, it is a right viewing angle. When viewed from a negative X direction toward a positive X direction, it is a left viewing angle. The X direction, Y direction, and Z direction are orthogonal to each other.

Referring to FIG. 1B, a top view of a display panel according to an embodiment of the disclosure is shown. A display panel 2 includes a plurality of pixel sets 10 arranged in an array on an XY plane. Each pixel set 10 includes two first pixels 100 and one second pixel 200. A Z direction in FIG. 1B is a positive viewing angle direction of the display panel 2. When viewed from a positive X direction toward a negative X direction, it is a right viewing angle. When viewed from a negative X direction toward a positive X direction, it is a left viewing angle. The X direction, Y direction, and Z direction are orthogonal to each other.

Referring to FIG. 1C, a top view of a display panel according to an embodiment of the disclosure is shown. A display panel 3 includes a plurality of pixel sets 10 arranged in an array on an XY plane. Each pixel set 10 includes three first pixels 100 and one second pixel 200. A Z direction in FIG. 1C is a positive viewing angle direction of the display panel 3. When viewed from a positive X direction toward a negative X direction, it is a right viewing angle. When viewed from a negative X direction toward a positive X direction, it is a left viewing angle. The X direction, Y direction, and Z direction are orthogonal to each other.

In FIG. 1A to FIG. 1C, ratios of the M first pixels 100 to the N second pixels 200 in a single pixel set 10 are 1, 2, and 3 respectively, but the disclosure is not limited thereto. In some embodiments, the ratio of M to N may be 4, 5, and 6.

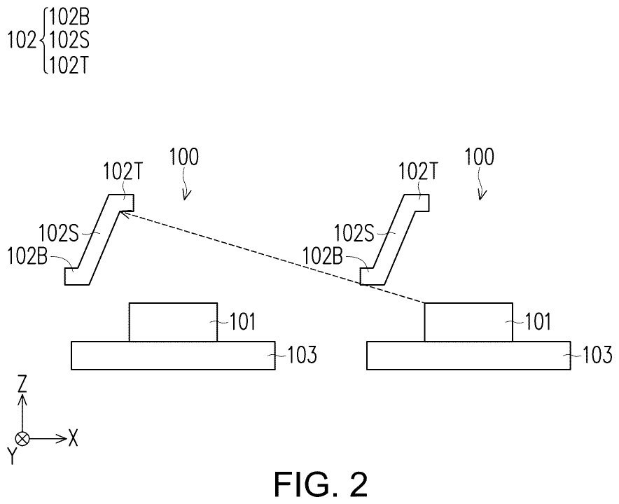

Referring to FIG. 2, a schematic diagram of a first pixel according to an embodiment of the disclosure is shown. The first pixel 100 includes a substrate 103, a light emitting element 101, and a light blocking structure 102. The light emitting element 101 is configured on the substrate 103. The light blocking structure 102 is configured on a light emitting side of the light emitting element 101 and includes a bottom portion 102B, a slope portion 102S, and a top portion 102T that are integrally formed. A surface of the light blocking structure 102 away from the light emitting element 101 has extremely low reflectivity for visible light to prevent ambient light reflection from affecting the display quality. An included angle between the slope portion 102S and the X direction is less than or equal to 70 degrees to maintain structural strength. The light emitting element 101 may be, for example, a micro light emitting diode, but the disclosure is not limited thereto. The light blocking structure 102 in any first pixel 100 is used to block the light emitted by the corresponding light emitting element 101 within a specific left viewing angle range, and may block large angle light leakage from different first pixels 100 and avoid crosstalk between different pixels. However, the disclosure is not limited thereto. In some embodiments not shown, the light blocking structure of the first pixel 100 is used to block the light emitted by the light emitting element 101 within a specific right viewing angle range.

Please refer to FIG. 1B and FIG. 2 at the same time. In some embodiments, FIG. 2 may be regarded as a cross-sectional view along line AA′ in the display panel 2 of FIG. 1B. As mentioned above, the light emission of the first pixel 100 within a specific left viewing angle range is limited. Each second pixel 200 includes a light emitting element, and each second pixel 200 may be a pixel without a light blocking structure, or a pixel with a light blocking structure symmetrically distributed corresponding to the left and right viewing angles. Moreover, for a single pixel set 10, the light emitting element 101 of each first pixel 100 and the light emitting element of each second pixel 200 emit light of a same color.

In the embodiment, the display panel 2 may provide a private mode and a normal mode. In the private mode, the light emitting element of each second pixel 200 is turned off, and only the light emitting elements 101 of the first pixels 100 emit light. Therefore, the display panel 2 is not visible within a specific left viewing angle range. Moreover, since the light emitting element 101 of each first pixel 100 and the light emitting element of each second pixel 200 in a single pixel set 10 emit light of a same color, the display panel 2 will not cause color shift as a result of turning off the light emitting element of each second pixel 200 in the private mode.

On the other hand, in the normal mode, the light emitting elements 101 of the first pixels 100 emit light, and the light emitting element of each second pixel 200 also emit light. Although the first pixels 100 are not visible within a specific left viewing angle range, the display panel 2 may still be viewed at both left and right viewing angles due to the light generated by the second pixels 200. Accordingly, the display panel 2 may simultaneously provide left viewing angle images and right viewing angle images in the normal mode, and limit the left viewing angle in the private mode.

It should be noted that the first pixel 100 shown in FIG. 2 is not limited to the first pixels 100 included in the display panel 2 shown in FIG. 1B. Each first pixel 100 in the display panel 1 shown in FIG. 1A and each first pixel 100 the display panel 3 shown in FIG. 1C may also have a structure as shown in FIG. 2.

To sufficiently describe various implementation examples and aspects of the disclosure, several other embodiments of the disclosure are described below. Note that the reference numerals and a part of the contents in the previous embodiment are applicable to the following embodiments, in which identical reference numerals indicate identical or similar components, and repeated descriptions of the same technical contents are omitted. For the detailed descriptions of the omitted parts, reference can be found in the previous embodiment, and no repeated description is contained in the following embodiments.

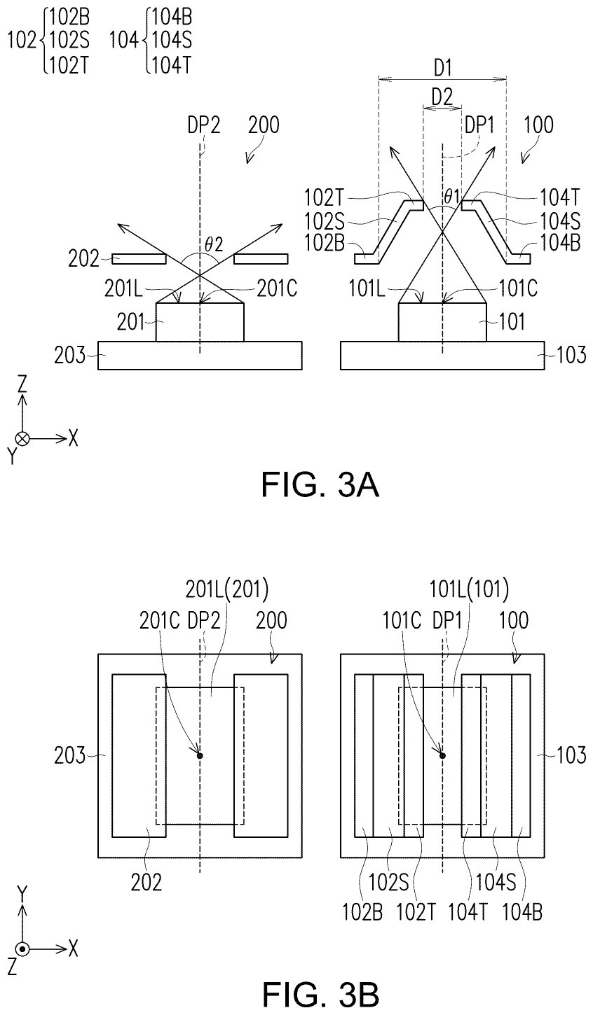

Referring to FIG. 1A, FIG. 3A, and FIG. 3B, FIG. 3A and FIG. 3B are schematic diagrams of first pixels and second pixels according to an embodiment of the disclosure. In the embodiment, FIG. 3A may be regarded as a cross-sectional view along line AA′ in the display panel 1 of FIG. 1A, where line AA′ is along the X direction. FIG. 3B is a top view corresponding to FIG. 3A.

The first pixel 100 includes the substrate 103, the light emitting element 101, the light blocking structure 102, and a light blocking structure 104. The light emitting element 101 is configured on the substrate 103. The three-dimensional light blocking structure 102 is configured on the light emitting side of the light emitting element 101 and includes the bottom portion 102B, the slope portion 102S, and the top portion 102T that are integrally formed. The three-dimensional light blocking structure 104 is configured on the light emitting side of the light emitting element 101 and includes a bottom portion 104B, a slope portion 104S, and a top portion 104T that are integrally formed. The slope portion 102S and the slope portion 104S have an included angle less than or equal to 70 degrees with the X direction to maintain structural strength. When the first pixel 100 is used in a transparent display, the above-mentioned included angle is preferably less than or equal to 45 degrees to avoid opacity or insufficient light transmittance at large viewing angles. The light blocking structure 102 is used to block the light emitted by the light emitting element 101 within a specific left viewing angle range. The light blocking structure 104 is used to block the light emitted by the light emitting element 101 within a specific right viewing angle range.

In the embodiment, the light blocking structure 102 and the light blocking structure 104 are disposed symmetrically with respect to a fictitious plane DP1. The fictitious plane DP1 passes through a geometric center 101C of a light emitting surface 101L of the light emitting element 101, and the vertical projections of the light blocking structure 102 and the light blocking structure 104 on the light emitting surface 101L do not overlap the geometric center 101C of the light emitting surface 101L. However, the disclosure is not limited thereto. The light blocking structure 102 and the light blocking structure 104 with respect to the fictitious plane DP1 may not be disposed symmetrically with respect to the fictitious plane DP1.

The second pixel 200 includes a substrate 203, a light emitting element 201, and a light blocking structure 202. The light emitting element 201 is configured on the substrate 203. For a single pixel set 10, the light emitting element 101 of each first pixel 100 and the light emitting element 201 of each second pixel 200 emit light of a same color. The planar light blocking structure 202 is configured on a light emitting side of the light emitting element 201 and is used to prevent crosstalk between the second pixel 200 and other adjacent pixels. The light blocking structure 202 is disposed symmetrically with respect to a fictitious plane DP2, and the fictitious plane DP2 passes through a geometric center 201C of a light emitting surface 201L of the light emitting element 201. It should be particularly noted that, although the light blocking structure 202 may block the light emitted by the light emitting element 201 within a specific left viewing angle range, it may also block the light emitted by the light emitting element 201 within a specific right viewing angle range. A horizontal viewing angle θ1 of the first pixel 100 is less than a horizontal viewing angle θ2 of the second pixel 200, as shown in FIG. 3A. Accordingly, the viewing angle of the display panel 1 may be further limited through the private mode to be described below.

In the embodiment, the display panel 1 may provide a private mode and a normal mode. In the private mode, the light emitting element 201 of each second pixel 200 is turned off, and only the light emitting elements 101 of the first pixels 100 emit light. Therefore, the display panel 1 has the horizontal viewing angle θ1 in the private mode. In addition, since the light emitting element 101 of each first pixel 100 and the light emitting element 201 of each second pixel 200 in a single pixel set 10 emit light of a same color, the display panel 1 will not cause color shift as a result of turning off the light emitting element 201 of each second pixel 200 in the private mode. On the other hand, in the normal mode, the light emitting elements 101 of the first pixels 100 emit light, and the light emitting element 201 of each second pixel 200 also emits light. Accordingly, the display panel 1 may have the horizontal viewing angle θ2 in the normal mode, and may have the horizontal viewing angle θ1 in the private mode, where θ2 is greater than θ1.

It should be noted that a distance D1 in the X direction between the bottom portion 102B of the light blocking structure 102 and the bottom portion 104B of the light blocking structure 104 is greater than a distance D2 in the X direction between the top portion 102T of the light blocking structure 102 and the top portion 104T of the light blocking structure 104, and greater than a width of the light emitting surface 101L in the X direction. Accordingly, the display panel 1 may use the top portion 102T of the light blocking structure 102 and the top portion 104T of the light blocking structure 104 to limit the horizontal viewing angle in the private mode, and use the bottom portion 102B and the slope portion 102S of the light blocking structure 102 and the bottom portion 104B and the slope portion 104S of the light blocking structure 104 for light blocking to avoid large angle light leakage in each first pixel 100. In addition, since the bottom portion 102B, the slope portion 102S, and the top portion 102T are integrally formed, and the bottom portion 104B, the slope portion 104S, and the top portion 104T are integrally formed, the light blocking structure 102 and the light blocking structure 104 may be manufactured at the same time, thereby reducing process complexity.

It should also be noted that compared with the situation in which the light blocking structure 202 is configured on the same layer as the top portion 102T of the light blocking structure 102 and the top portion 104T of the light blocking structure 104 in a comparative example, the light blocking structure 202 of the embodiment is configured on the same layer as the bottom portion 102B of the light blocking structure 102 and the bottom portion 104B of the light blocking structure 104, so that the light blocking structure 202 is closer to the light emitting surface 201L of the light emitting element 201 in the Z direction, so as to further prevent each second pixel 200 from large angle light leakage.

It should be noted that, the first pixel 100 and the second pixel 200 shown in FIG. 3A and FIG. 3B are not limited to being included in the display panel 1 shown in FIG. 1A. Each first pixel 100 and each second pixel 200 in the display panel 2 shown in FIG. 1B and each first pixel 100 and each second pixel 200 in the display panel 3 shown in FIG. 1C may also have the structure as shown in FIG. 3.

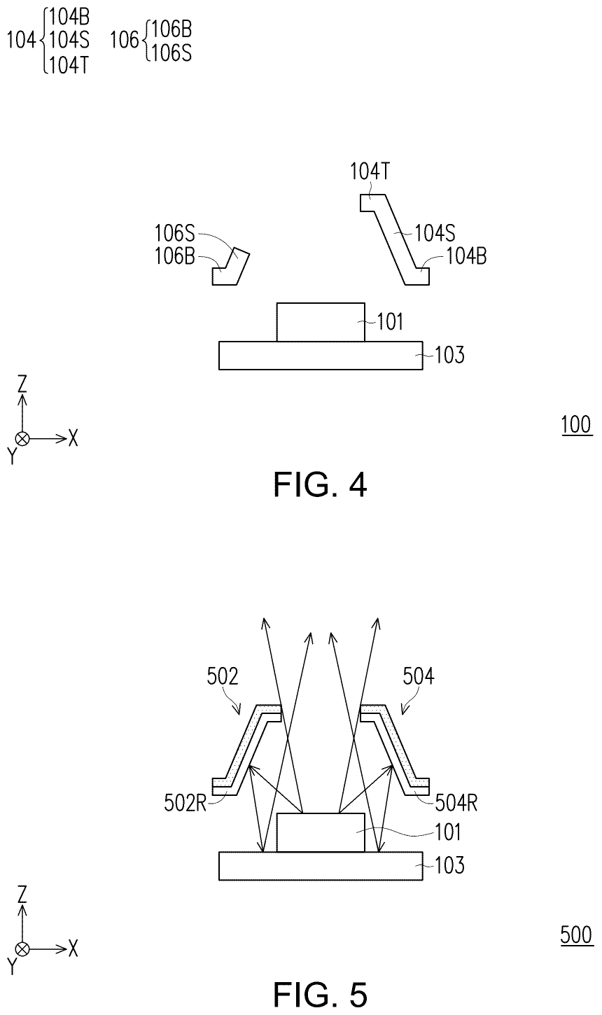

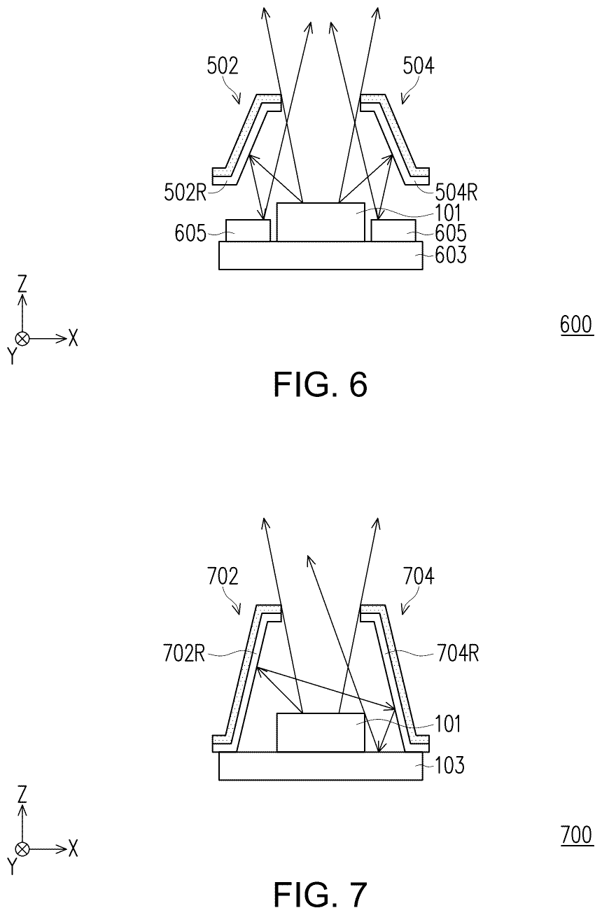

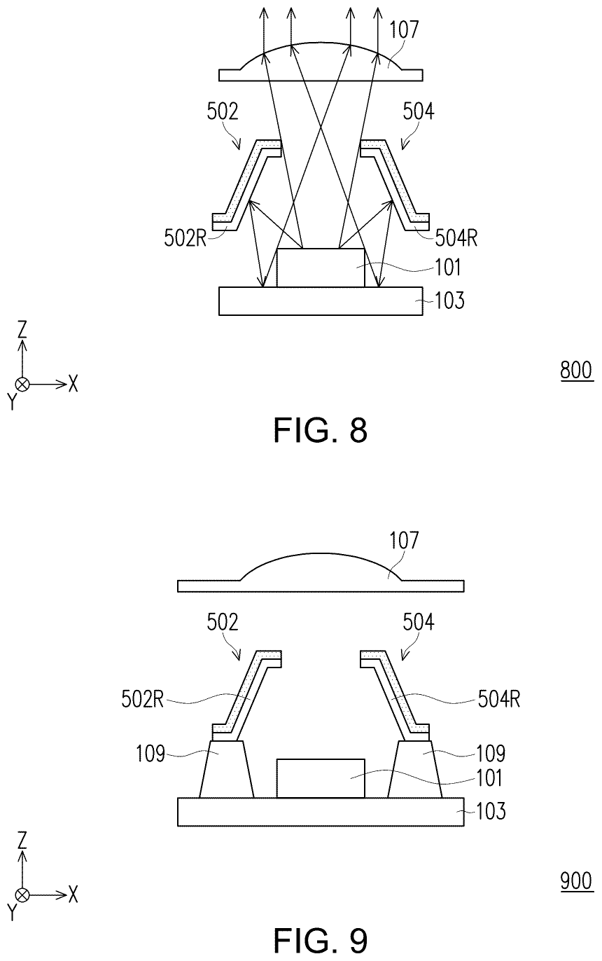

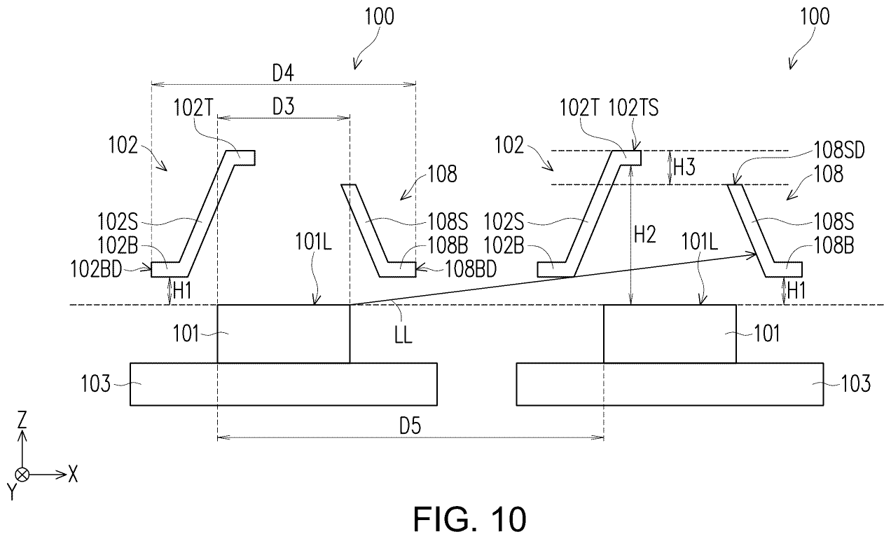

Next, please refer to FIG. 4 to FIG. 10 to understand various variations of the first pixel provided according to embodiments of the disclosure.

Referring to FIG. 4, a schematic diagram of a first pixel according to an embodiment of the disclosure is shown. The first pixel 100 includes the substrate 103, the light emitting element 101, the light blocking structure 104, and a light blocking structure 106. The light emitting element 101 is disposed on the substrate 103. The three-dimensional light blocking structure 104 is configured on the light emitting side of the light emitting element 101 and includes the bottom portion 104B, the slope portion 104S, and the top portion 104T that are integrally formed to block the light emitted by the light emitting element 101 within a specific right viewing angle range. The three-dimensional light blocking structure 106 is configured on the light emitting side of the light emitting element 101 and includes a bottom portion 106B and a slope portion 106S that are integrally formed. A length of the slope portion 106S of the light blocking structure 106 is less than a length of the slope portion 104S of the light blocking structure 104, so as to allow the first pixel 100 to be visible within a specific left viewing angle range. The bottom portion 106B and the slope portion 106S are used for light blocking to avoid large angle light leakage from the left viewing angle.

Referring to FIG. 5, a schematic diagram of a first pixel according to an embodiment of the disclosure is shown. A first pixel 500 includes the substrate 103, the light emitting element 101, a light blocking structure 502, and a light blocking structure 504. The light emitting element 101 is configured on the substrate 103, where the substrate 103 includes metal. The three-dimensional light blocking structure 502 is configured on the light emitting side of the light emitting element 101 and includes a reflective layer 502R facing the light emitting element 101. The three-dimensional light blocking structure 504 is configured on the light emitting side of the light emitting element 101 and includes a reflective layer 504R facing the light emitting element 101. Accordingly, the light emitted from the light emitting element 101 and blocked by the light blocking structure 502 and the light blocking structure 504 will be reflected by the reflective layer 502R and the reflective layer 504R, and subsequently reflected by the substrate 103, and then emitted from the first pixel 500 through the opening formed by the light blocking structure 502 and the light blocking structure 504, thereby increasing the brightness of the first pixel 500 in the positive viewing angle direction. In other words, the embodiment uses the three-dimensional light blocking structure 502 and the light blocking structure 504 to achieve the light collection effect.

Referring to FIG. 6, a schematic diagram of a first pixel according to an embodiment of the disclosure is shown. A first pixel 600 includes a substrate 603, the light emitting element 101, the light blocking structure 502, the light blocking structure 504, and a reflective layer 605. The light emitting element 101 is configured on the substrate 603. The three-dimensional light blocking structure 502 is configured on the light emitting side of the light emitting element 101 and includes the reflective layer 502R facing the light emitting element 101. The three-dimensional light blocking structure 504 is configured on the light emitting side of the light emitting element 101 and includes the reflective layer 504R facing the light emitting element 101. The reflective layer 605 is configured on the substrate 603 and has high reflectivity for visible light. The reflective layer 605 may include metal, for example, but the disclosure is not limited thereto. Accordingly, the light emitted from the light emitting element 101 and blocked by the light blocking structure 502 and the light blocking structure 504 will be reflected by the reflective layer 502R and the reflective layer 504R, and subsequently reflected by the reflective layer 605, and then emitted from the first pixel 600 through the opening formed by the light blocking structure 502 and the light blocking structure 504, thereby increasing the brightness of the first pixel 600 in the positive viewing angle direction.

Referring to FIG. 7, a schematic diagram of a first pixel according to an embodiment of the disclosure is shown. A first pixel 700 includes the substrate 103, the light emitting element 101, a light blocking structure 702, and a light blocking structure 704. The light emitting element 101 is configured on the substrate 103, where the substrate 103 includes metal. The three-dimensional light blocking structure 702 is configured on the substrate 103 and contacts the substrate 103. The three-dimensional light blocking structure 704 is configured on the substrate 103 and contacts the substrate 103. When the first pixel 700 is applied in a transparent display, the light blocking structure 702 and the light blocking structure 704 contacting the substrate 103 may ensure that the light emitted by the light emitting element 101 does not leak when viewed from the back of the transparent display. The light blocking structure 702 includes a reflective layer 702R facing the light emitting element 101, and the light blocking structure 704 includes a reflective layer 704R facing the light emitting element 101. Accordingly, the light emitted from the light emitting element 101 and blocked by the light blocking structure 702 and the light blocking structure 704 will be reflected by the reflective layer 702R and the reflective layer 704R, and subsequently reflected by the substrate 103, and then emitted from the first pixel 700 through the opening formed by the light blocking structure 702 and the light blocking structure 704, thereby increasing the brightness of the first pixel 700 in the positive viewing angle direction.

Referring to FIG. 8, a schematic diagram of a first pixel according to an embodiment of the disclosure is shown. A first pixel 800 includes the substrate 103, the light emitting element 101, a light blocking structure 502, a light blocking structure 504, and a microlens 107. The light emitting element 101 is configured on the substrate 103, where the substrate 103 includes metal. The three-dimensional light blocking structure 502 is configured on the light emitting side of the light emitting element 101 and includes the reflective layer 502R facing the light emitting element 101. The three-dimensional light blocking structure 504 is configured on the light emitting side of the light emitting element 101 and includes the reflective layer 504R facing the light emitting element 101. The light blocking structure 502 and the light blocking structure 504 are configured between the light emitting element 101 and the microlens 107. Accordingly, the light emitted from the light emitting element 101 and blocked by the light blocking structure 502 and the light blocking structure 504 will be reflected by the reflective layer 502R and the reflective layer 504R, and subsequently reflected by the substrate 103, and then pass through the opening formed by the light blocking structure 502 and the light blocking structure 504, and is emitted from the first pixel 800 after transmitting through the microlens 107, thereby increasing the brightness of the first pixel 800 in the positive viewing angle direction. In the embodiment, a diameter of the microlens 107 on the XY plane may be less than or equal to 100 microns, and a maximum thickness of the microlens 107 in the Z direction may be less than or equal to 50 microns, but the disclosure is not limited thereto.

Referring to FIG. 9, a schematic diagram of a first pixel according to an embodiment of the disclosure is shown. A first pixel 900 includes the substrate 103, the light emitting element 101, the light blocking structure 502, the light blocking structure 504, the microlens 107, and a blocking wall 109. The light emitting element 101 is configured on the substrate 103, where the substrate 103 includes metal. The three-dimensional light blocking structure 502 is configured on the light emitting side of the light emitting element 101 and includes the reflective layer 502R facing the light emitting element 101. The three-dimensional light blocking structure 504 is configured on the light emitting side of the light emitting element 101 and includes the reflective layer 504R facing the light emitting element 101. The light blocking structure 502 and the light blocking structure 504 are configured between the light emitting element 101 and the microlens 107. The blocking wall 109 is configured between the light blocking structure 502 and the light blocking structure 504 and the substrate 103, and has high reflectivity for visible light. The blocking wall 109 may directly contact the light blocking structure 502 and the light blocking structure 504 as shown in FIG. 9 or have a gap between the light blocking structure 502 and the light blocking structure 504. The surface of the blocking wall 109 facing the light emitting element 101 may have an included angle in the range of 90 degrees to 150 degrees with the substrate 103. Accordingly, the light emitted from the light emitting element 101 and blocked by the light blocking structure 502 and the light blocking structure 504 will be reflected by the reflective layer 502R and the reflective layer 504R, and subsequently reflected by the substrate 103 and the blocking wall 109, and then pass through the opening formed by the light blocking structure 502 and the light blocking structure 504, and is emitted from the first pixel 900 after transmitting through the microlens 107, thereby increasing the brightness of the first pixel 900 in the positive viewing angle direction.

Please refer to FIG. 1B and FIG. 10 at the same time. FIG. 10 is a schematic diagram of a first pixel according to an embodiment of the disclosure. In the embodiment, FIG. 10 may be regarded as a cross-sectional view along line AA′ in the display panel 2 of FIG. 1B, and the two first pixels 100 shown in FIG. 10 refer to any two first pixels 100 arranged adjacently in the X direction in the display panel 2.

In the embodiment, each first pixel 100 includes the substrate 103, the light emitting element 101, the light blocking structure 102, and a light blocking structure 108. The light blocking structure 102 is configured on the light emitting side of the light emitting element 101 and includes the bottom portion 102B, the slope portion 102S, and the top portion 102T that are integrally formed. The light blocking structure 108 is configured on the light emitting side of the light emitting element 101 and includes a bottom portion 108B and a slope portion 108S that are integrally formed. Furthermore, the bottom portion 102B and the bottom portion 108B are configured in the same layer, and both have a distance H1 from the light emitting surface 101L of the light emitting element 101 in the Z direction. There is a distance H2 between the top portion 102T and the light emitting surface 101L of the light emitting element 101 in the Z direction. An end 108SD of the slope portion 108S away from the light emitting element 101 and a top surface 102TS of the top portion 102T away from the light emitting element 101 are spaced apart by a distance H3 in the Z direction. The light emitting surface 101L of the light emitting element 101 has a width D3 in the X direction. An end 102BD of the bottom portion 102B away from the light emitting element 101 and an end 108BD of the bottom portion 108B away from the light emitting element 101 are spaced apart by a distance D4 in the X direction. Furthermore, the two light emitting elements 101 arranged adjacently in the X direction have a pitch D5. If the distance H1 meets the following conditional formula:

$$H 1 < ( H 2 - H 3 ) \times \frac{D 4 - D 3}{D 4 - D 3 + ( 2 \times D 5 )}$$

when the large-angle light emitted by the light emitting element 101 of one of the two first pixels 100 is not blocked by the light blocking structure 108 due to the distance H1 between the corresponding bottom portion 108B and the light emitting surface 101L of the light emitting element 101 (a beam LL as shown in FIG. 10), the large-angle light may be blocked by the light blocking structure 108 of the other of the two first pixels 100 to avoid large angle light leakage, as shown in FIG. 10.

In summary, the display panel provided by the embodiment of the disclosure uses the first pixels and the second pixels with different light blocking structures to switch between the normal mode and the private mode. The top portion of the light blocking structure in the first pixel is used to limit the horizontal viewing angle of the display panel, the bottom portion and the slope portion of the light blocking structure in the first pixel are used to avoid large angle light leakage, and the three-dimensional light blocking structure has a light collection effect, so that energy consumption can be reduced.

What is claimed is:

1. A display panel comprising a plurality of pixel sets, each of the pixel sets comprising at least one first pixel and at least one second pixel, wherein
the at least one first pixel comprises:
a first light emitting element; and
a first light blocking structure, configured on a light emitting side of the first light emitting element, and comprising a bottom portion, a slope portion, and a top portion that are integrally formed,
the at least one second pixel comprises:
a second light emitting element, emitting light of a same color as the first light emitting element; and
a second light blocking structure, configured on a light emitting side of the second light emitting element, wherein the second light blocking structure is disposed symmetrically with respect to a first fictitious plane, and the first fictitious plane passes through a geometric center of a light emitting surface of the second light emitting element.

2. The display panel according to claim 1, wherein each of the pixel sets comprises M first pixels and N second pixels, a ratio of M to N is greater than or equal to 1, and less than or equal to 6, and M and N are positive integers.

3. The display panel according to claim 1, wherein a vertical projection of the first light blocking structure on a light emitting surface of the first light emitting element does not overlap a geometric center of the light emitting surface.

4. The display panel according to claim 1, wherein the first light blocking structure is a three-dimensional structure, and the second light blocking structure is a planar structure.

5. The display panel according to claim 1, wherein the second light blocking structure is configured on a same layer as the bottom portion of the first light blocking structure.

6. The display panel according to claim 1, wherein the at least one first pixel further comprises a third light blocking structure, and the third light blocking structure is configured on the light emitting side of the first light emitting element and comprises a bottom portion, a slope portion, and a top portion that are integrally formed.

7. The display panel according to claim 6, wherein the first light blocking structure and the third light blocking structure are disposed symmetrically with respect to a second fictitious plane, and the second fictitious plane passes through a geometric center of a light emitting surface of the first light emitting element.

8. The display panel according to claim 6, wherein the second light blocking structure, the bottom portion of the first light blocking structure, and the bottom portion of the third light blocking structure are configured on a same layer.

9. The display panel according to claim 6, wherein a horizontal viewing angle of the at least one first pixel is less than a horizontal viewing angle of the at least one second pixel.

10. The display panel according to claim 6, wherein a distance between the bottom portion of the first light blocking structure and the bottom portion of the third light blocking structure is greater than a distance between the top portion of the first light blocking structure and the top portion of the third light blocking structure.

11. The display panel according to claim 1, wherein the at least one first pixel further comprises a third light blocking structure, comprising a bottom portion and a slope portion that are integrally formed, and a length of the slope portion of the first light blocking structure is greater than a length of the slope portion of the third light blocking structure.

12. The display panel according to claim 11, wherein a distance between the bottom portion of the first light blocking structure and the bottom portion of the third light blocking structure and a light emitting surface of the first light emitting element in a positive viewing angle direction of the display panel is the same.

13. The display panel according to claim 12, wherein the bottom portion of the first light blocking structure and the light emitting surface of the first light emitting element have a first distance (H1) in the positive viewing angle direction, the top portion of the first light blocking structure and the light emitting surface have a second distance (H2) in the positive viewing angle direction, a first end of the slope portion of the third light blocking structure away from the light emitting element and a top surface of the top portion of the first light blocking structure away from the light emitting element are spaced apart by a third distance (H3) in the positive viewing angle direction, the light emitting surface has a width (D3) in a first direction perpendicular to the positive viewing angle direction, a second end of the bottom portion of the first light blocking structure away from the light emitting element and a third end of the bottom portion of the third light blocking structure away from the light emitting element are spaced apart by a fourth distance (D4) in the first direction, a plurality of first light emitting elements of the display panel have a pitch (D5) in the first direction, and the first distance (H1) meets the conditional formula
$$H 1 < ( H 2 - H 3 ) \times \frac{D 4 - D 3}{D 4 - D 3 + ( 2 \times D 5 )} .$$

14. The display panel according to claim 1, wherein the first light blocking structure comprises a reflective layer facing the first light emitting element.

15. The display panel according to claim 1, wherein the at least one first pixel further comprises a microlens, and the first light blocking structure is configured between the first light emitting element and the microlens.
